(19) United States
(12) Patent Application Publication
(10) Pub. No.: US 2017/0222181 A1
(43) Pub. Date: Aug. 3, 2017

(54) DISPLAY DEVICE

(71) Applicant: Japan Display Inc., Tokyo (JP)

(72) Inventors: Tetsuya NAGATA, Tokyo (JP); Yoshinori Ishii, Tokyo (JP)

(21) Appl. No.: 15/487,469

(22) Filed: Apr. 14, 2017

Related U.S. Application Data
(63) Continuation of application No. 14/498,026, filed on Sep. 26, 2014.

(30) Foreign Application Priority Data
Sep. 26, 2013 (JP) 2013-199616

(51) Int. Cl. H01L 51/52; H01L 51/56; H01L 27/32

(52) U.S. Cl. CPC H01L 51/5246; H01L 27/322; H01L 51/56; H01L 2251/558

(57) ABSTRACT

A display device includes a first substrate having a first step part formed in a frame area on a periphery of a display area, a second substrate arranged facing the first substrate, and a filler material filled between the first substrate in one part of the display area and the frame area, and the second substrate, a periphery edge part being located in a range from the first step part to an end part of the first substrate and the second substrate.

### CROSS-REFERENCE TO RELATED APPLCIATIONS

This application is based upon and claims the benefit of priority from the prior Japanese Patent Application No. 2013-199616, filed on 26 Sep. 2013, the entire contents of which are incorporated herein by reference.

### FIELD

The present invention is related to a display device and a method of forming the same.

### BACKGROUND

Display devices using a light emitting element which uses an OLED (Organic Light-Emitting Diode) are being developed. This type of display device is formed by bonding together a substrate including a TFT circuit or OLED light emitting element and a substrate including a color filter etc. by filling a filler material.

FIG. 12 shows a planar view diagram of a display device 100 related to one embodiment of a conventional example. During bonding of the substrates, coating a dam material 11 on a frame area so that a filler material does not protrude above one of the substrates, dripping a filler agent onto the inner side of a filler material filling area 104 which is enclosed by the dam material 11 and bonding to the other substrate using reduced pressure are a typical series of manufacturing methods. FIG. 13 shows a cross section of the line C-C′ in FIG. 12. By bonding a first substrate 120 and a second substrate 130 together, a filler material 112 is filled into a space enclosed by the first substrate 120, second substrate 130 and the dam material 11. That is, the filler material filling area 104 is defined by the range enclosed by the dam material 11.

Generally, a material with high viscosity such as a few tens of thousands mPa·s is used as a dam material so that a filler material within an area enclosed by the dam material does not exceed the dam material and spread to the exterior. A certain period of time is required in order to coat such a high viscosity material which is an obstacle from the view point of reducing manufacturing time.

In addition, when bonding substrate, the internal filler material enclosed by the dam material does not spread well and non-filled areas near the dam material sometimes remain as bubbles (vacuum pool). FIG. 14 is a planar view diagram showing and expanded view of the upper right vicinity of FIG. 12 and shows the generation of bubbles in a display device related to embodiment of a conventional example. Referring to FIG. 14, it can be seen that bubble 14 is produced near the dam material 11 within the filler material filling area 104, and the range of the spreading bubble 14 reaches not only the frame area 102 but as far as the display area 101. When this type of bubble reaches a display area of a display device, an area filled with a filler material and a non-filled area are strikingly confirmed visually and display quality is significantly lost.

Furthermore, with an increase in the demand for large screens and miniaturization of devices in a display which uses a display device, the demand for narrowing a frame area (narrow frame) as much as possible also increases. However, it is necessary to form a dam material in a frame area and also a certain width is also required in order to emit a filler material to the exterior. In addition, as is shown in FIG. 14, considering the case where bubbles are produced near the dam material, it is necessary that the distance up to the dam material from the boundary of a display area and frame area be designed while providing a certain leeway. Therefore, usage of a dam material becomes a hindrance to narrowing a frame.

With respect to this point, a display device exists which is formed by bonding a substrate just with a filler material and without using a dam material (for example, Patent Document 1 [Japanese Laid Open Patent 2008-59945]).

However, the Patent Document 1 does not describe a method for defining a filling area of a filler material. As a result, the filler material sometimes protrudes when bonding a substrate.

### SUMMARY

According to one embodiment of the present invention, a display device is provided including a first substrate having a first step part formed in a frame area on a periphery of a display area, a second substrate arranged facing the first substrate, and a filler material filled between the first substrate in one part of the display area and the frame area, and the second substrate, a periphery edge part being located in a range from the first step part to an end part of the first substrate and the second substrate.

According to one embodiment of the present invention, a display device is provided, wherein the first substrate includes a color filter formed on a part of the display area and the frame area, and the first step is formed by etching the color filter.

According to one embodiment of the present invention, a display device is provided, wherein the second substrate includes a second step part formed on a part facing the frame area of the first substrate.

According to one embodiment of the present invention, a display device is provided, wherein the second substrate is formed with a transistor including an organic interlayer insulation film, and the second step part is formed by etching a part of the organic interlayer insulation film.

According to one embodiment of the present invention, a display device is provided, wherein the first step part is formed by flat surface or curved surface bonding.

According to one embodiment of the present invention, a display device is provided, wherein the second step part is formed by flat surface or curved surface bonding.

According to one embodiment of the present invention, a display device is provided further including a terminal area contacting an outer side of the frame area, wherein the first step part is formed in the frame area on a side near the terminal area, and on the frame area on the opposing side sandwiched by the terminal area and the display area.

According to one embodiment of the present invention, a manufacturing method of a display device is provided including forming a first step part in a frame area of a periphery of a display area of a first substrate, forming a filler material filling area including the display area using the first step part, dripping a filler material to the filler material filling area, and bonding a facing second substrate to the first substrate.

According to one embodiment of the present invention, a manufacturing method of a display device is provided, wherein the first step is formed by etching a color filter formed on one part of the frame area.

According to one embodiment of the present invention, a manufacturing method of a display device is provided, wherein a second step part is formed on a part facing the frame area part of the first substrate on the second substrate.

According to one embodiment of the present invention, a manufacturing method of a display device is provided, wherein the second substrate is formed with a transistor including an organic interlayer insulation film, and the second step part is formed by etching a part of the organic interlayer insulation film.

According to one embodiment of the present invention, a manufacturing method of a display device is provided, wherein the first step part is formed by flat surface or curved surface bonding.

According to one embodiment of the present invention, a manufacturing method of a display device is provided, wherein the second step part is formed by flat surface or curved surface bonding.

According to one embodiment of the present invention, a manufacturing method of a display device further includes a terminal area contacting an outer side of the frame area, wherein the first step part is formed in the frame area on a side near the terminal area, and on the frame area on the opposing side sandwiched by the terminal area and the display area.

### BRIEF DESCIPTION OF DRAWINGS

FIG. 1 is a planar view diagram of a display device related to a first embodiment of the present invention.

FIG. 2 is a planar view diagram of a display device related to the first embodiment of the present invention.

FIG. 3 is a planar view diagram of a display device related to the first embodiment of the present invention.

FIG. 4 is a planar view diagram of a display device related to the first embodiment of the present invention.

FIG. 5 is a device multi-display device imposition arrangement diagram related to the first embodiment of the present invention.

FIG. 6 is a coating arrangement diagram of a step part, a periphery seal and a filler material related to the first embodiment of the present invention.

FIG. 7 is a substrate bonding process diagram related to the first embodiment of the present invention.

FIG. 8 is a cross-sectional diagram of a display device related to a second embodiment of the present invention.

FIG. 9 is an exploded view diagram of one part of a planar view of a display device related to a third embodiment of the present invention.

FIG. 10 is a planar view diagram of a display device related to a fourth embodiment of the present invention.

FIG. 11 is a device multi-display device imposition arrangement diagram related to the fourth embodiment of the present invention.

FIG. 12 is a planar view diagram of a display device related to an embodiment of a conventional example.

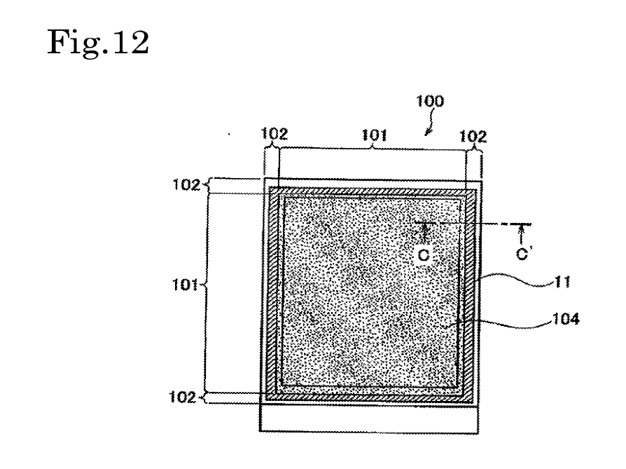

FIG. 13 is a cross-sectional diagram of a display device related to an embodiment of a conventional example.

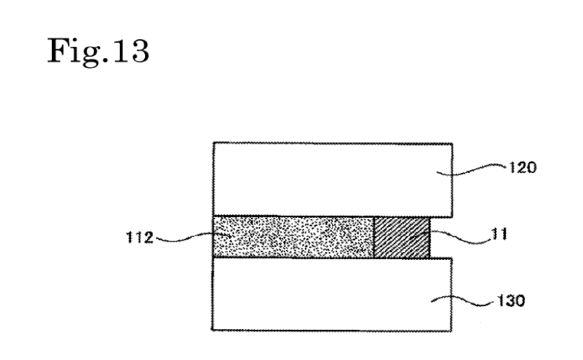

FIG. 14 is a diagram shown the production of bubbles in a planar view of a display device related to an embodiment of a conventional example.

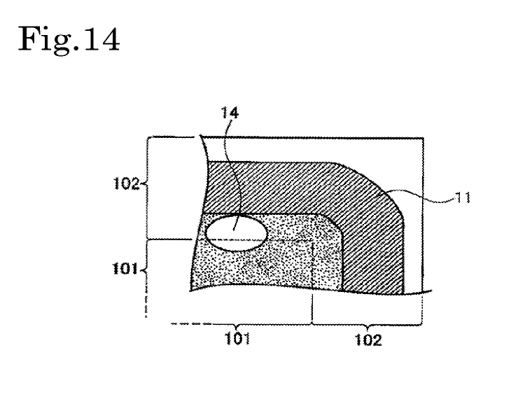

### DESCRIPTION OF EMBODIMENTS

The embodiments of the display device of the present invention are explained below while referring to the drawings. Furthermore, the embodiments shown below are an example of embodiments of the present invention, the present should not be interpreted as being limited to the these embodiments and various modifications can be performed. Furthermore, in the drawings referenced in the embodiments, the same reference symbols are attached to the same parts or parts having similar functions and repeated explanations may be omitted. In addition, the dimension proportions in the drawings may different to the actual proportions for the purpose of explanation and parts of the structure may be omitted from the drawings. In addition, forming above a substrate means not only forming to contact the substrate but also includes forming a structure wherein other structural parts may be inserted between the substrate.

### First Embodiment

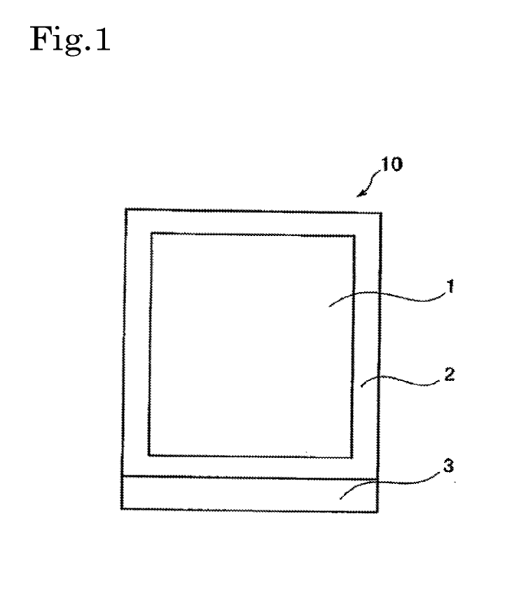

FIG. 1 show a planar view diagram of an OLED display device 10 related to the first embodiment of the present invention. The OLED display device 10 can be divided into a display area 1 which displays an image, a terminal area 3 which performs connection with external drive circuits, and a frame area. Here, the frame area refers to an area from the display area 1 to an exterior periphery of a display device. Although not shown in FIG. 1, for example a plurality of control signal wires which run in a horizontal direction, a plurality of data signal wires which run in a vertical direction, a power supply wire, and a plurality of TFT circuits etc arranged in a matrix in the vicinity of an intersection part of the control signal wires and data signal wires are arranged within the display area 1. In addition, a pixel part arranged in a matrix corresponding to each TFT circuit may be arranged within the display area 1 and the display area 1 can display an image.

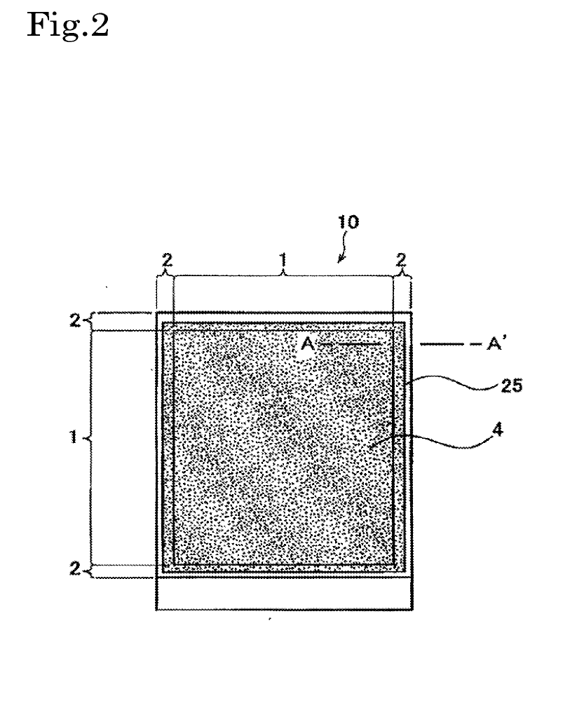

FIG. 2 shows a planar perspective diagram of the OLED display device related to the first embodiment of the present invention. A step part 25 is formed in the frame area 2 so as to enclose the display area 1. A filler material is filled in the entire area enclosed by the step part 25 to form a filler material filling area 4. Therefore, the filler material filling area 4 is formed to cover at least the entire display area 1.

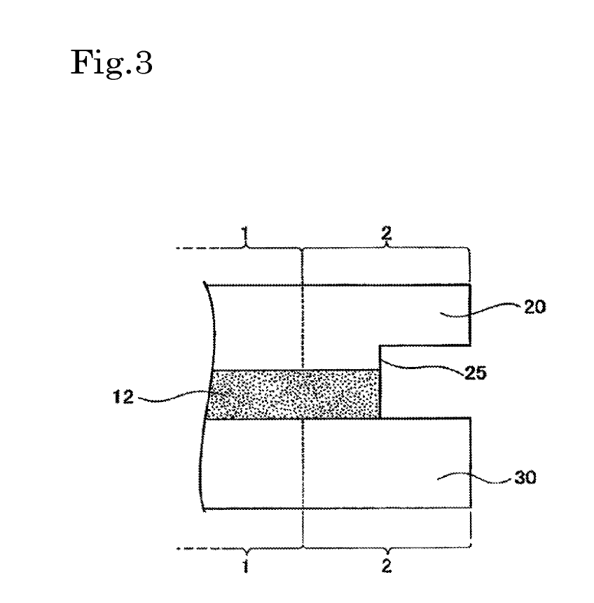

FIG. 3 shows a cross sectional view of the OLED display device related to the first embodiment of the present invention and shows the part A-A′ in FIG. 2. The OLED display device related to the first embodiment of the present invention includes a structure whereby a filler material 12 is filled between a first substrate 20 and second substrate 30 to bond the substrates. Although not shown in FIG. 3, the first substrate 20 is formed with a color filter and a light shielding film above a transparent glass substrate. Furthermore, a translucent film (overcoat) is formed and a surface formed with the overcoat contacts the filler material 12. In addition, the second substrate 30 is formed with a TFT circuit layer, an electrode layer, an OLED light emitting later and a sealing layer etc in this order above a glass substrate. A surface on which the sealing layer of the second substrate 30 is formed contacts the filler material 12.

The step part 25 is arranged on a part which contacts the frame area 2 above the first substrate 20. An interval is arranged between the first substrate 20 and the second substrate 30 with the filler material filling area 4 side being narrow and the frame area 2 on the outer side of the filler material filling area 4 being wide. As is stated below, the filler material 12 is dripped onto the filler material filling area 4 of the first substrate 20, the dripped filler material 12 is pushed and spread out by bonding the first substrate and second substrate 30 together and the filler material 12 is filled over the entire filler material filling area 4. That is, the filler material 12 exceeds the display area 1 and is filled up to the step part 25 formed in the frame area 2 to form the filler material filling area 4.

During the process of arriving at the present invention, the inventors performed an experiment related to spreading the filler material 12 by arranging an appropriate step on the first substrate 20 or second substrate 30 and confirmed that a narrow part of the interval between the substrates encouraged spreading of the filler material 12 and a wide part of the interval between the substrates suppressed spreading of the filler material 12. Considering this phenomenon, it is assumed that spreading of filler material is blocked by the surface tension of the filler material in the step part where the interval between the substrate becomes wider as a reason for being able to define the range of the filler material 12 being spread by arranging the step part 25 on the first substrate 20

The angle of the step is formed from 30 degrees to 90 degrees from a horizontal direction and preferably from 60 degrees to 90 degrees. 90 degrees or more is also preferred from the effects of stopping the spread of the filled material. However, because overhang occurs in this case, it is necessary to confirm the presence of damage, peeling and other defects to such parts during the manufacture process.

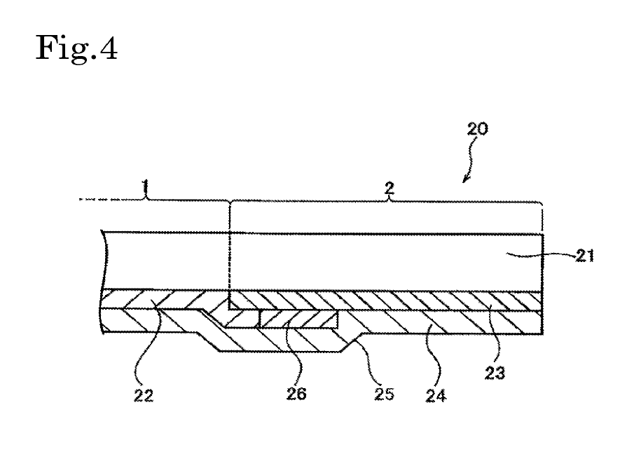

FIG. 4 shows a cross section of the display device related to the first embodiment of the present invention and one example of the first embodiment.

The first substrate 20 is formed with a color filter 22 and a light shielding film 23 on a glass substrate 21 with the main component being a transparent blank glass, and is formed by forming an overcoat 24 which covers the color filer 22 and light shielding film 23. The color filter 22 is formed in the display area 1 and a filer of a desired color of a corresponding pixel is used. In addition, the light shielding film 23 is formed in order to prevent light of the OLED formed in the display area 1 of the second substrate 30 leaking in the frame area 2. Although not shown in FIG. 4, the light shielding film 23 is sometimes formed above a boundary line of each pixel within the display area 1.

With regards to the formation sequence of the color filter 22 and light shielding film 23, first the light shielding film 23 is formed above the substrate 21, then the color filter 22 is formed. In the case where the color filter 22 and light shielding film 23 are formed in this sequence, although a section of the light shielding film 23 and color filter 22 overlap, considering the technical issues related to the present invention, since finding a utility for the color filter 22 in this section is difficult, usually a color filter 22 which suppresses this overlapping is formed. However, in the first embodiment of the present invention, the color filter 22 is arranged to overlap the light shielding film 23. A dummy color filter 26 refers to a part of a color filter arranged to overlap the light shielding film 23. The dummy color filter 26 may be formed by extending the color filter 22 adjacent to the light shielding film 23 or a separate color filter to the color filter arranged adjacent to the light shielding film 23 may be arranged. In either case, the dummy filter 26 can be arranged without significant design changes from the existing manufacturing process.

As an alternative method of forming a step, there is a method of simultaneously forming a step at the time of forming a pillar shaped spacer on a color filter substrate. After coating a photosensitive resist for a pillar shaped spacer, a band shape is formed for forming a spacer shape and periphery step by lithography. At this time, the band shaped step formation part can be formed at a lower height than the pillar shaped spacer by performing a half exposure.

The step part 25 is formed on a side surface of the dummy filter by arranged the dummy filter 26 in the frame area 2. The thickness of the dummy filter 22 (dummy color filter 26) is 1˜5 μm, and a step is produced with a thickness equal to a part where the dummy color filter of the 26 of the frame area 2 is present and where it is not present. However, the thickness of the color filter 22 (dummy filter 26) is not limited to the range described above.

Below, an explanation is given according to the manufacturing process of the display device related to the first embodiment of the present invention.

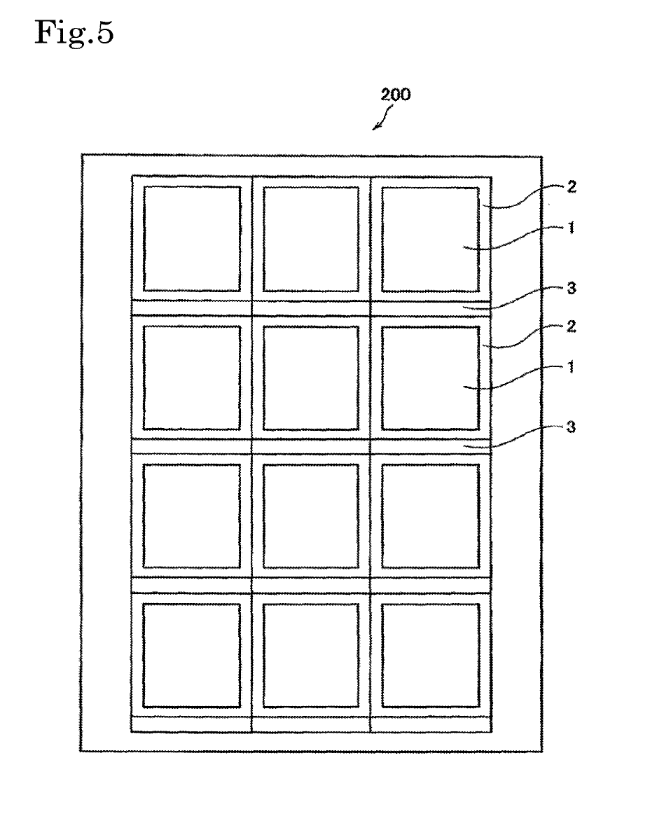

FIG. 5 shows a multi-display device imposition first substrate of an OLED display device related to the first embodiment of the present invention. The structure of the OLED display device is formed with a plurality of display device patterns above a single glass substrate considering production yield, that is, multi-display device imposition is usually performed. In FIG. 3, a single first substrate 20 is formed by the frame area 2, the display device 1 enclosed by the frame area 2 and a terminal area 3 adjacent to the bottom side of the frame area 2. Although the first substrate 20 is imposed with a total of 12 surfaces, four vertical and 3 horizontal, a multi-display device imposition structure depends on the size of the OLED display device and the size of the glass substrate but is not limited to this. The light shielding film 23, color filter 22, dummy filter 26 and overcoat 24 are formed while in the multi-display device imposition state.

Furthermore, the second substrate 30 and first substrate 20 are also multi-surface imposed. The first substrate 20 and second substrate 30 are bonded together while in a multi-display device imposition state and subsequently cut and each forming an OLED display device.

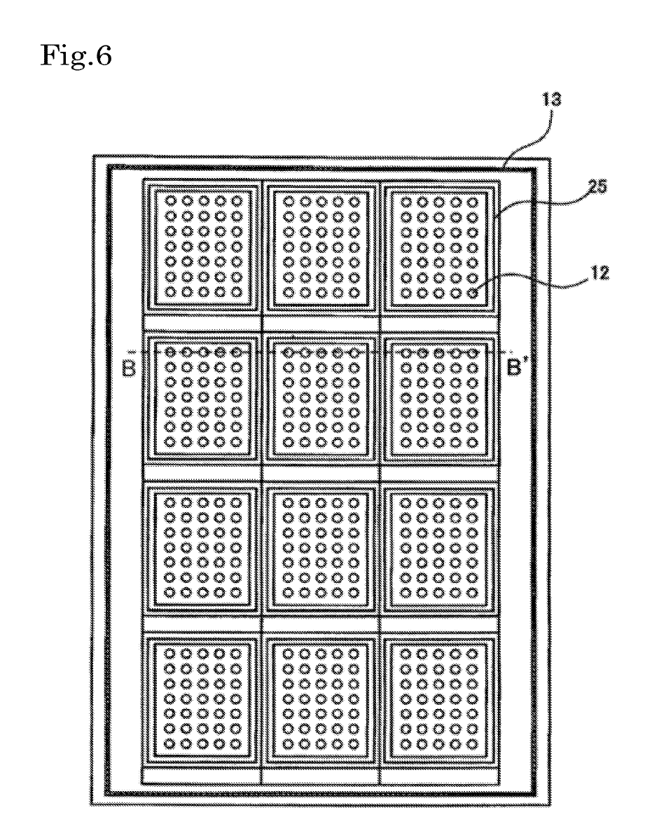

FIG. 6 shows a coating arrangement of the step part 25, periphery seal 3 and filler material 12 in the first embodiment of the present invention. The filler material 12 is dripped in drops into the interior of the filler material filling area 4 (not shown in the diagram) enclosed by the step part 25 using a liquid quantitative discharge device such as a dispenser. The filler material 12 is dripped in drops in order to form globe shapes from the filler material 12 due to surface tension. The filler material 12 is regularly dripped while maintaining a fixed interval in a matrix shape.

A UV curing type or thermosetting type transparent resin such as epoxy resin or acryl resin for example are used for the filler material 12. It is also possible to use a similar material such as a UV delaying curing type material. In this type, viscosity increases where the curing reaction progresses after a certain period of time following irradiating the UV light, after 10 minutes for example. By using this material, UV is irradiated to the entire surface of a substrate coated with the filler material and curing is performed by heating after bonding the substrate.

In addition, the periphery seal 13 is coated near the outer edge of the multi-display device imposed first substrate 20. A resin having thermosetting properties such as an infrared curing type resin for example is used for the periphery seal 13. Furthermore, although not shown FIG. 6, a spacer material is also appropriately coated while maintaining a fixed interval between the first substrate 20 and second substrate 30.

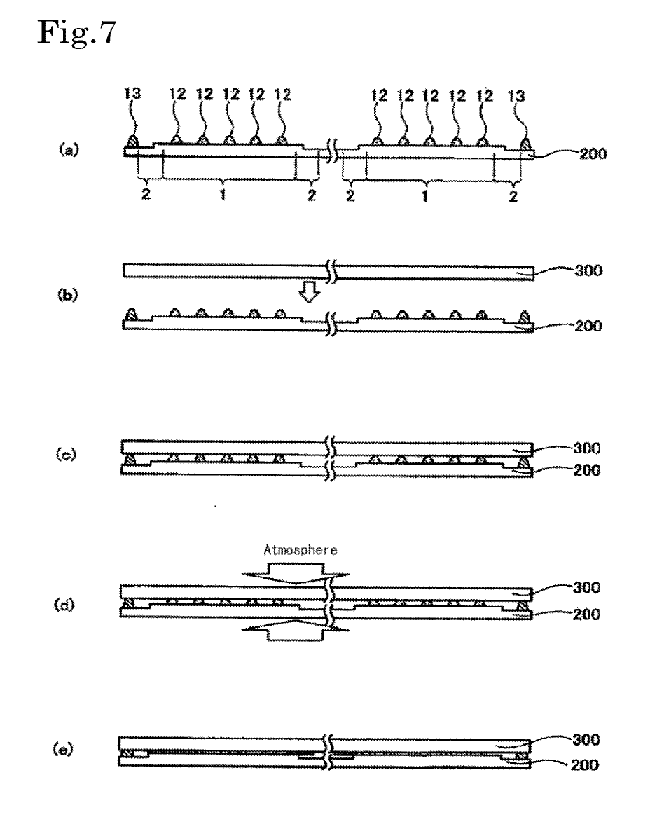

FIG. 7 shows a bonding process diagram of a substrate related to the first embodiment of the present invention.

FIG. 7 (a) shows that state whereby the filler material 12 and periphery seal 13 are coated above the multi-display device imposed first substrate 200. The step part 25 is formed in the multi-display device imposed first substrate 200. A thick part and thin part are formed in the multi-display device imposed first substrate 200 by the step part 25 and the thick part corresponds to the filler material filling area 4. The periphery seal 13 is coated on both ends of the multi-display device imposed first substrate 200.

FIG. 7 (b) shows the state whereby the multi-display device imposed first substrate 200 shown in FIG. 7 (a) and the multi-display device imposed second substrate 300 face each other. The multi-display device imposed first substrate 200 and multi-display device imposed second substrate 300 are introduced to a reduced pressure chamber, the pressure within the chamber is reduced and an interval between the substrates is narrowed while positioning using an alignment mark etc formed on both substrates according to necessity.

FIG. 7 (c) shows the state whereby the multi-display device imposed first substrate 200 and the multi-display device imposed second substrate 300 are in contact. The multi-display device imposed first substrate 200, the multi-display device imposed second substrate 300 which faces the multi-display device imposed first substrate 200, and a closed space are formed by 2 periphery seals 13 sandwiched between the substrates by a plurality of the filler material 12.

Since this closed space is formed under a state of reduced pressure, the multi-display device imposed first substrate 200 and multi-display device imposed second substrate 300 are pushed together by the atmosphere. This appearance is shown in FIG. 7 (d).

FIG. 7 (e) shows the state whereby the space formed between the periphery seal 13, the multi-display device imposed first substrate 200 and multi-display device imposed second substrate 300 is crushed and the filler material 12 is filled into the filler material filling area 4. The filler material 12 is filled only in the part where the interval between the multi-display device imposed first substrate 200 and multi-display device imposed second substrate 300 is narrow.

After the substrate bonding process shown in FIG. 7 is performed, the bonded substrates are introduced to a curing oven and the filling material 12 undergoes a thermosetting process. In this way, in the case where a thermosetting type filler material 12 is used, there is an effect whereby an infrared irradiation process is no longer required after bonding compared to the case of combining with a UV curing type dam material in the conventional technology. The multi-display device imposed first substrate 200 and multi-display device imposed second substrate 300 are adhered by the filler material 12 by the process described above and the bonded substrate is completed.

The bonded substrate is separated by cutting each OLED display device using a method such as scribe breaking. In addition, since the part which faces the terminal area 3 of the second substrate 30 is removed by cutting, the terminal area 3 of the OLED display device is formed just by the second substrate.

Production of the step related to the first embodiment of the present invention is not limited to the method described above. For example, it is possible to produce the step by not forming the dummy color filter 26 and removing the overcoat 23 of the frame area 2 by photolithography for example.

According to the first embodiment of the present invention, it is possible to define and suppress spreading of a filler material by forming a step in a substrate when bonding 2 substrates by filling a filler material. In addition, because it is possible to remove all or a part of a dam material formed so as to enclose all of a display area in the conventional technology, it is possible to reduce the amount of the dam material and reduce the number of processes when coating the dam material to a substrate. Furthermore, it is possible to realize a narrow frame of a frame area by not using all or part of the dam material.

### Second Embodiment

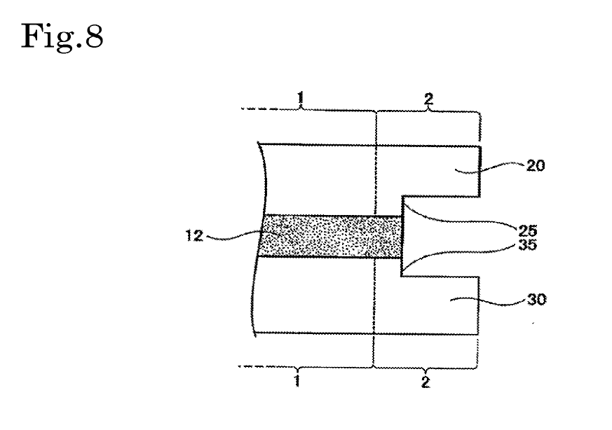

FIG. 8 is a cross sectional diagram of a display device related to the second embodiment of the present invention and shows the part A-A′ in FIG. 2. In the second embodiment, a step part 35 is formed on the second substrate 30. The step part 35 can be formed for example by removing a part of the organic interlayer insulation film of the second substrate 30.

Viewing FIG. 8, the step part 25 of the first substrate 20 and the step part 35 of the second substrate 30 are formed in the same position when seen from the front of the display device, that is, the direction shown in FIG. 2, however, the second embodiment is not limited to this. However, the positions of the step part 25 of the first substrate 20 and the step part 35 of the second substrate 30 are preferred to match as much as possible when seen from the front of the display device.

In addition, the step parts of the display device can be formed without forming the step part 25 of the first substrate and just by the step part 35 of the second substrate 30.

### Third Embodiment

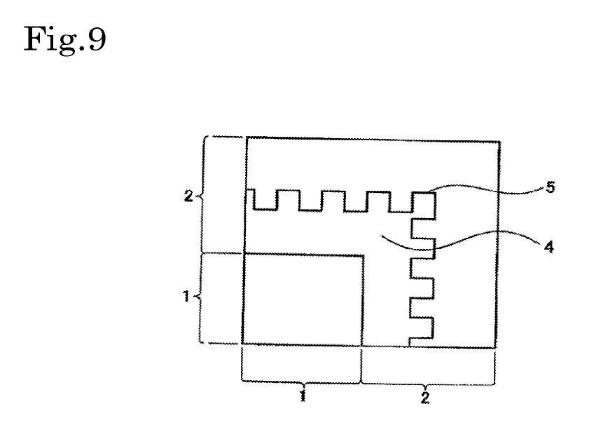

FIG. 9 is a planar view diagram of a display device related to the third embodiment of the present invention and shows an enlarged view of the upper right vicinity in FIG. 2. The shape of the step part 25 seen from a planar view is a square convex-concave shape. The shape of the step part 25 related to the third embodiment seen from a planar view is not limited to this. For example, other than a straight line shape, various shapes such as a serrated shape or arc shape are possible. In addition, although the step part 25 is formed in a square convex-concave shape in FIG. 9, it is possible to partially form the step from shapes other than a straight line or from lines of a plurality of shapes.

By forming the step part using shapes other than a straight line when seen from a planar view, the periphery length of the step part 25 which encloses the filler material filling area 4 becomes longer when compared to a straight line shape. This means that with regards to the filler material 12 which is spread by bonding of the substrates, parts which are exposed to the part where the interval between the first substrate 20 and second substrate 30 is wide increase and it is possible to further improve the effect of suppressing spreading of the filler material.

In addition, it is possible to obtain similar effects as those described above by also forming the shape of the step part 35 of the second substrate 30 into a square convex-concave shape as described above.

### Fourth Embodiment

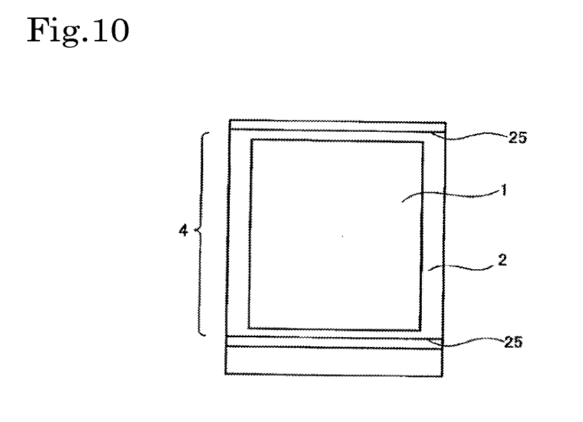

FIG. 10 shows a planar view of a display device related to the fourth embodiment of the present invention. In the fourth embodiment, the step part 25 is formed in a horizontal direction on the frame area 2 on the top side of the display device 1 and on the frame area 2 on the bottom side of the display device 1 respectively. Here, the area enclosed by the step part 25 on top and bottom of the display device 1 and an outer edge of the display device becomes the filler material filling area 4.

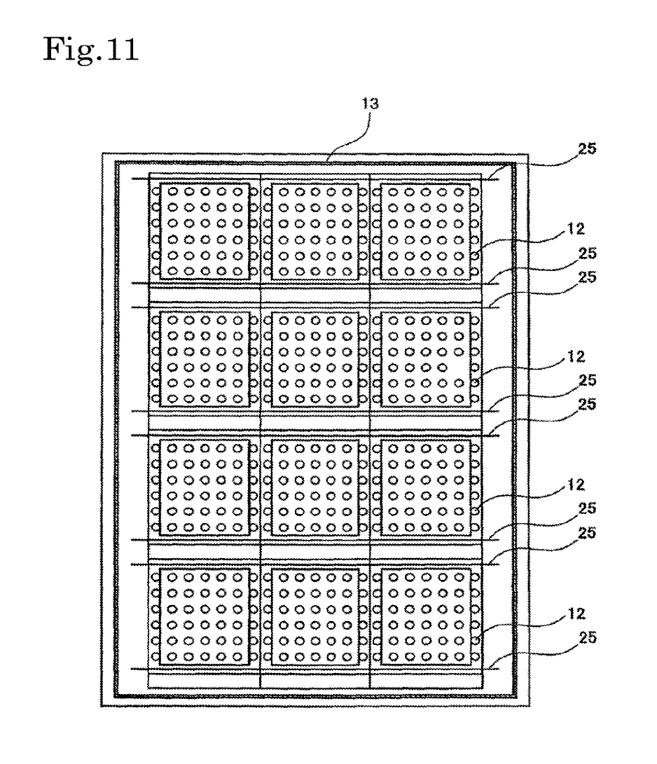

FIG. 11 shows the multi-display device imposed first substrate 200 related to the fourth embodiment of the present invention. The step part 25 is formed in the frame area 2 on the top side and bottom side of each display device 1 above the multi-display device imposed first substrate 200 respectively. As described above, since the part corresponding to the terminal area 3 of the first substrate 20 is removed by cutting after bonding, it is not desirable that the filler material 12 entering the terminal area 3. Thus, in the fourth embodiment, the step part 25 formed on the bottom side of the display area 1 is prevented from entering the terminal area 3 of the filler material 12 and the filler material 12 is prevented from entering the terminal area 3 of the first substrate 20 to which the step part 25 formed on the top side of the display area 1 is adjacent.

In addition, viewing FIG. 11 it can be seen that the step part 25 is formed not only in the frame area 2 but also up to the outer side of the frame area 2 of the first substrate 1 arranged on the left and right ends. In this way, by forming the step part 25 extending to near the outer edge of the multi-display device imposed first substrate 200, it is possible to effectively prevent the filer material 12 spread by bonding the substrate from entering a connection part 3 around the step part 25.

### Fifth Embodiment

In the first to fourth embodiments, it is assumed that the first and second substrates are contacted in a reduced pressure chamber in the substrate bonding process, and subsequently the pressure in the chamber is returned to an atmospheric pressure and the substrates are bonded by the atmospheric pressure. However, the present invention is not limited to this. In the fifth embodiment, a manufacturing device which can perform bonding of the substrates using a pressure equivalent to atmospheric pressure is used. In this case, since gap formation of the filler material is completed without exposure to air, the periphery seal 13 shown in FIG. 6 becomes unnecessary. It is possible to reduce costs and manufacturing processes related to the periphery seal 13 by adopting these manufacturing processes, increase the number of surfaces by the size of the display device which produces cost reduction effects.

### Other Modification Examples

In FIG. 3 and FIG. 8, a cross section of the step part 25 and step part 35 is formed perpendicularly and in this case, the step part 25 and step part 35 are formed by a flat surface. However, the present invention is not limited to this. The step part 25 and step part 35 may also be formed using a curve.

In addition, in FIG. 3 and FIG. 8, although the filler material 12 is filled up to the step part 25 or the step part 35 to form a perpendicular cross section, the present invention is not limited to this. The filler material 12 may also be filled beyond the step part 25 or the step part 35 or may not be filled up to the step part 25 or the step part 35. In addition, the cross section of the filler material 12 does not have to be formed perpendicularly.

Furthermore, although the dam material is not included as a structural component in the first to fifth embodiments, the present invention is not limited to this and may also include a part of the dam material.

What is claimed is:

1. A display device comprising:
a first substrate having a display area and a frame area outside the display area, the first substrate having a first step part in the frame area;
a second substrate facing the first substrate; and
a filler material between the first substrate and the second substrate, wherein
the filler material entirely covers the display area in a planar view,
the filler material includes a first periphery edge part,
the first periphery edge part is located between the first step part and an end part of the first substrate,
the filler material continuously extends from the display area to the first periphery edge part without any interface, and
the first periphery edge part is exposed to an outer surface of the display device in a view from a direction of the end part of the first substrate.

2. The display device according to claim 1, wherein
the second substrate has a second step part facing the first step part.

3. The display device according to claim 1, wherein
a thickness of the filler material at the display area is smaller than a distance between the end part of the first substrate and an end part of the second substrate.

4. The display device according to claim 1, wherein
the first substrate includes a first organic interlayer on a base material, and
the first step part is formed by removing a part of the first organic interlayer.

5. The display device according to claim 2, wherein
the second substrate includes a second organic interlayer on a base material, and
the second step part is formed by removing a part of the second organic interlayer.

6. The display device according to claim 1, wherein
the filler material has a second periphery edge part at an opposite side of the first periphery edge part across the display area,
the display area is between the first periphery edge part and the second periphery edge part, and
the filler material continuously extends from the first periphery edge part to the second periphery edge part without any interface.

7. The display device according to claim 1, wherein
the first step part has a convex-concave shape, a serrated shape, or an arc shape in a planar view.

8. The display device according to claim 2, wherein
the second step part has a convex-concave shape, a serrated shape, or an arc shape in a planar view.

9. The display device according to claim 2, wherein
a thickness of the filler material at the display area is smaller than a distance between the end part of the first substrate and an end part of the second substrate.

10. The display device according to claim 9, wherein
the first substrate includes a first organic interlayer on a base material, and
the first step part is formed by removing a part of the first organic interlayer.

11. The display device according to claim 10, wherein
the second substrate includes a second organic interlayer on a base material, and
the second step part is formed by removing a part of the second organic interlayer.

12. The display device according to claim 11, wherein
the filler material has a second periphery edge part at an opposite side of the first periphery edge part across the display area,
the display area is between the first periphery edge part and the second periphery edge part, and
the filler material continuously extends from the first periphery edge part to the second periphery edge part without any interface.

13. The display device according to claim 12, wherein
the first step part has a convex-concave shape, a serrated shape, or an arc shape in a planar view.
